(19) United States
(12) Patent Application Publication
(10) Pub. No.: US 2024/0371614 A1
(43) Pub. Date: Nov. 7, 2024

(54) METHOD FOR WASHING SUBSTRATE TREATMENT APPARATUS

(71) Applicant: JUSUNG ENGINEERING CO., LTD., Gwangju-Si, Gyeonggi-Do (KR)

(72) Inventors: Jeong HEO, Gwangju-Si, Gyeonggi-Do (KR); Il Houng PARK, Gwangju-Si, Gyeonggi-Do (KR); Won Ju OH, Gwangju-Si, Gyeonggi-Do (KR); Dong Hwan LEE, Gwangju-Si, Gyeonggi-Do (KR); Jun Seok LEE, Gwangju-Si, Gyeonggi-Do (KR); Byung Gwan LIM, Gwangju-Si, Gyeonggi-Do (KR); Seung Hyun CHO, Gwangju-Si, Gyeonggi-Do (KR)

(21) Appl. No.: 18/682,952

(22) PCT Filed: Sep. 20, 2022
(86) PCT No.: PCT/KR2022/014051

§ 371 Date: Feb. 12, 2024

(30) Foreign Application Priority Data
Sep. 24, 2021 (KR) 10-2021-0126347

(51) Int. Cl. H01J 37/32; B08B 5/00; B08B 9/00; H01L 21/02

(52) U.S. Cl. CPC H01J 37/32862; B08B 5/00; B08B 9/00; H01J 37/32449; H01J 2237/332; H01L 21/02554; H01L 21/02565

(57) ABSTRACT

Provided is a method for cleaning a substrate processing apparatus. The method includes loading a substrate into a chamber, injecting a gas containing at least one of Zn, Ga, In, or Sn into the chamber to deposit a thin film on the substrate, unloading the substrate to the outside of the chamber, injecting a cleaning gas containing Br into the chamber, and exhausting byproducts generated through a reaction between impurities deposited inside the chamber in addition to the substrate and the cleaning gas in the depositing of the thin film. Therefore, the inside of the apparatus may be cleaned at relatively low temperature. That is, impurities having the form of the thin film, which are deposited on a surface of a component or structure installed inside the apparatus may be delaminated from the surface.

### TECHNICAL FIELD

The present disclosure relates to a method for cleaning a substrate processing apparatus, and more particularly, to a method for cleaning a substrate processing apparatus, which is capable of reducing an amount of impurities remaining in the substrate processing apparatus.

### BACKGROUND ART

A process of manufacturing a semiconductor device or a display device includes a process of depositing a thin film on a substrate. In addition, the process of depositing the thin film is performed inside a chamber of the substrate processing apparatus.

When the deposition process of depositing the thin film on the substrate is performed, deposits may be deposited not only on the substrate but also the inside of the chamber, in which the deposition process is performed. For example, the thin film is deposited on an inner wall of the chamber, a surface of a support, which supports the substrate, or the like.

When the thin film deposited inside the chamber increases in thickness, the thin film are delaminated to cause a generation of particles. In addition, the particles may be introduced into the thin film formed on the substrate or attached to the surface of the thin film to act as a cause of defects, thereby increasing in defect rate of products. Therefore, it is necessary to remove the deposits before being delaminated.

When a cleaning process for removing the deposits inside the chamber is performed, a gas containing Cl or a gas containing F has been used generally. Here, to allow the gas containing Cl or the gas containing F to react with the deposits, the inside of the chamber has to be maintained at a high temperature.

However, when the deposits are delaminated from the surface inside the chamber, the temperature inside the chamber is high, and thus, a surface of a component or structure on which the deposits are deposited may be delaminated together with the deposits. Thus, contaminants acting as impurities are additionally generated in addition to the deposits. As a result, there is a limitation in that an amount of impurities including the deposits and the additionally generated contaminants in the chamber is large, and thus, a large amount of impurities remain in the chamber even after the cleaning process is completed.

In addition, as the inside of the chamber is maintained at the high temperature, there is a limitation in that corrosion occurs inside the chamber during the cleaning process.

### Related Art Document

(patent document 1) Korean Patent Registration No. 10-1232904

### SUMMARY

### Technical Problem

The present disclosure provides a method for cleaning a substrate processing apparatus that is capable of performing cleaning at a low temperature.

The present disclosure also provides a method for cleaning a substrate processing apparatus that is capable of performing cleaning at a temperature less than a thin film deposition temperature.

### Technical Solution

In accordance with an exemplary embodiment, a method for cleaning a substrate processing apparatus includes: loading a substrate into a chamber; injecting a gas containing at least one of Zn, Ga, In, or Sn into the chamber to deposit a thin film on the substrate; unloading the substrate to the outside of the chamber; injecting a cleaning gas containing Br into the chamber; and exhausting byproducts generated through a reaction between impurities deposited inside the chamber in addition to the substrate and the cleaning gas in the depositing of the thin film.

In accordance with another exemplary embodiment, a method for cleaning a substrate processing apparatus includes: loading a substrate into a chamber; injecting a gas into the chamber to deposit a thin film on the substrate; unloading the substrate to the outside of the chamber; injecting a cleaning gas containing Br into the chamber; and exhausting byproducts generated through a reaction between impurities deposited inside the chamber in addition to the substrate and the cleaning gas in the depositing of the thin film, wherein in the injecting of the cleaning gas, the cleaning gas is pulsed and injected or the cleaning gas and the exhausting of the byproducts are alternately repeated.

The method may further include injecting a first auxiliary gas, which decomposes the cleaning, into the chamber.

The first auxiliary gas may use at least one of an H₂ gas or an O₂ gas.

The method may further include generating plasma in the chamber.

The generating of the plasma may include injecting a second auxiliary gas that is an Ar gas.

The method may further include injecting a gas containing nitrogen into the chamber, wherein the injecting of the gas containing the nitrogen may be performed between the injecting of the cleaning gas and the exhausting of the byproducts.

The cleaning gas may use a gas containing at least one of HBr, KBr, Br₂, HBr O₃, or CBr F₃.

A temperature inside the chamber may be less than a temperature when the deposition is performed.

### Advantageous Effects

In accordance with the exemplary embodiments, the inside of the substrate processing apparatus may be cleaned at the temperature that is relatively low when compared to the related art and less than the deposition process temperature. That is, the impurities having the form of the thin film, which are deposited on the surface of the component or structure installed inside the substrate processing apparatus may be delaminated from the surface so as to be cleaned at the low temperature.

Thus, the surface inside the substrate processing apparatus may be prevented from being peeled off together when the impurities are delaminated. Therefore, the generation of the additional contaminants in the chamber may be reduced, and the amount of impurities remaining in the substrate processing apparatus after the cleaning process is completed may be reduced.

In addition, the occurrence of the corrosion of the substrate processing apparatus due to the high-temperature heat may be prevented or suppressed.

### BRIEF DESCRIPTION OF THE DRAWINGS

FIG. 1 is a process diagram illustrating a cleaning process in situ after a deposition process in accordance with an exemplary embodiment;

FIG. 2 is a process diagram illustrating a cleaning process in situ after a deposition process in accordance with another exemplary embodiment; and

FIG. 3 is a view illustrating a substrate processing apparatus that performs cleaning through the methods in accordance with exemplary embodiments.

### DETAILED DESCRIPTIONS OF EXEMPLARY EMBODIMENTS

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The drawings may be exaggerated to describe the embodiments of the present invention, and like reference numerals in the drawings refer to the same elements.

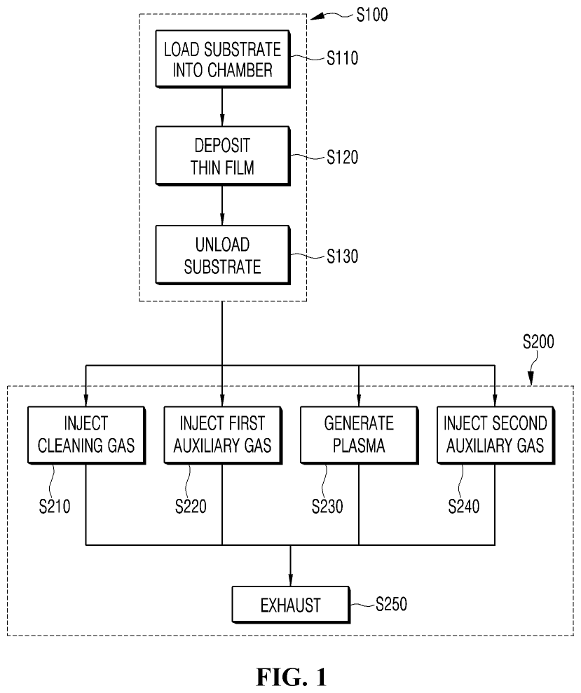

FIG. 1 is a process diagram illustrating a cleaning process in situ after a deposition process in accordance with an exemplary embodiment.

A cleaning process may be a process of removing a thin film deposited or accumulated on a surface of a component or structure other than a substrate when the thin film is deposited on the substrate in a substrate processing apparatus

Hereinafter, for convenience of description, the thin film deposited or accumulated on the surface of the component or structure other than the substrate in the substrate processing apparatus and remaining in the substrate processing apparatus is referred to as impurities.

In an exemplary embodiment, a deposition process (S100) and a cleaning process (S200) are performed in situ in one substrate processing apparatus as illustrated in FIG. 1. That is, after the process (S100) of depositing the thin film on the substrate in the substrate processing apparatus is completed, the process (S200) of cleaning the inside of the substrate processing apparatus is performed. Here, the cleaning process may be performed immediately after one deposition process is performed, or the cleaning process may be performed after a plurality of deposition processes are performed. In addition, the cleaning process may be selectively performed between the deposition processes.

Referring to FIG. 1, the deposition process (S100) includes a process (S110) of loading a substrate into a chamber of a substrate processing apparatus, a process (S120) of depositing a thin film on one surface of the substrate, and a process (S130) of unloading the substrate, on which the thin film is deposited, to the outside of the chamber.

The thin film deposited in the deposition process (S120) may be a zinc oxide (ZnO) thin film or a thin film, into which at least one of In (indium), Ga (gallium), or Sn (tin) is doped, on the substrate. More specifically, the deposition process may be a process of depositing any one of a zinc oxide (ZnO) thin film, an indium zinc oxide (IZO) thin film to which In (indium) is doped into zinc oxide (ZnO), a gallium zinc oxide (GZO) thin film in which Ga (gallium) is doping into zinc oxide (ZnO), an indium gallium zinc oxide (IGZO) thin film in which In (Indium) and Ga (Gallium) are doped into zinc oxide (ZnO), and an indium tin zinc oxide (ITZO) thin film in which In (Indium) and Sn (Tin) are doped into zinc oxide (ZnO) on the substrate. In addition, the deposition process (S100) forming the thin film may be, for example, a process of forming an active layer of a thin film transistor.

In addition, the deposition process performed before or after the cleaning process in accordance with an exemplary embodiment may be a process of depositing the thin film on the substrate through an atomic layer deposition (ALD) method.

In addition, the process temperature for depositing a zinc oxide (ZnO) thin film, an indium zinc oxide (IZO) thin film, a gallium zinc oxide (GZO) thin film, and an indium gallium zinc oxide (IGZO) thin film may be approximately 300° C. to approximately 350° C. (approximately 300° C. or more and approximately 350° C. or less). In addition, the process temperature for depositing the indium tin zinc oxide (ITZO) thin film may be approximately 250° C. to approximately 400° C. (approximately 250° C. or more and approximately 400° C. or less).

As illustrated in FIG. 1, the cleaning process (S200) includes a process (S210) of injecting a cleaning gas that is a gas containing bromine (Br), a process (S220) of injecting a first auxiliary gas that is a gas, which decomposes or activates the cleaning gas, and a process (S250) of exhausting the gases.

In addition, the cleaning process (S200) may include a process (S230) of generating plasma in a space in which the cleaning gas and the first auxiliary gas are injected. In addition, the cleaning process (S200) may further include a process (S240) of injecting the cleaning gas and a second auxiliary gas, which is a different type of gas from the first auxiliary gas. Here, the second auxiliary gas may be a gas injected to improve plasma generation efficiency.

When the cleaning process is performed after the deposition process is completed, the cleaning process is performed at a temperature less than a process temperature for the deposition process. That is, the cleaning is performed at a temperature of less than approximately 300° C. (room temperature or more) or a temperature of less than approximately 250° C. (room temperature or more). For this, a gas that is capable of being decomposed or activated at a temperature less than the process temperature, at which the thin film is deposited on the substrate, is used as the cleaning gas. In other words, a gas that is capable of being decomposed or activated at a temperature of less than 300° C. (more than room temperature) is used as the cleaning gas.

In this embodiment, a gas containing bromine (Br) is used as the cleaning gas. As a more specific example, a gas containing at least one of HBr, KBr, Br₂, HBr O₃, or CBr F₃ is used as the cleaning gas. Gases containing bromine (Br), such as HBr, KBr, Br₂, HBr O₃, and CBr F₃, may be decomposed or activated at a temperature of less than 300° C. (more than room temperature). That is, the cleaning gas containing bromine (Br) may be decomposed at a temperature less than a temperature required for reaction between a source gas and a reactant gas, which are gases for depositing the thin film.

The first auxiliary gas may be a gas that reacts with the cleaning gas to decompose the cleaning gas, and at least one of H₂ gas or O₂ gas may be used as the first auxiliary gas. Here, the first auxiliary gas may be injected through a path different from that of the cleaning gas.

The impurities may be deposited or accumulated in the form of the thin film on the surface of various components or structures in the substrate processing apparatus. The impurities that are in the form of the thin film are not easily delaminated or separated from the surface of various components or structures.

However, the cleaning gas containing Br reacts with the impurities or deposits that are in the form of the thin film, and thus, the impurities (deposits) are delaminated from the surface. In addition, during the deposition, the impurities may be delaminated from the surface by reacting with the impurities at a temperature less than the process temperature.

Hereinafter, the cleaning process using the cleaning gas and the first auxiliary gas will be described. In this case, a case in which the HBr gas is used as the cleaning gas, and the H₂ gas is used as the first auxiliary gas will be described as an example. In addition, a case in which the cleaning process is performed after performing a process of depositing a ZnO thin film on the substrate in the substrate processing apparatus will be described as an example.

After the process of depositing the ZnO thin film on the substrate is performed in the substrate processing apparatus, the ZnO thin film may be deposited on surfaces of various components or structures as well as the substrate. As described above, the ZnO thin film deposited on a surface other than the substrate in the substrate processing apparatus, that is, the ZnO deposit may act as impurities contaminating the substrate or the thin film during the subsequent deposition process.

Thus, when the deposition process (S100) is completed, the cleaning process is performed (S200). For this, the cleaning gas and the first auxiliary gas are injected into the substrate processing apparatus. That is, the HBr gas as the cleaning gas and the H₂ gas as the first auxiliary gas are injected. In addition, the temperature inside the substrate processing apparatus is adjusted to a temperature of less than approximately 300° C.

When the cleaning gas (HBr gas) and the first auxiliary gas (H₂) are injected, HBr that is the cleaning gas is decomposed by the first auxiliary gas H₂, and a reaction between Br decomposed from the cleaning gas and the ZnO thin film that is the impurities occurs (see Reaction formula 1).

ZnO+2HBr+H₂→ZnBr₂·H₂O (Reaction Formula 1)

That is, ZnO, which is a deposit remaining in the substrate processing apparatus, is decomposed, and thus, Zn Br₂·H₂O is generated. In other words, the impurities that are in the form of the ZnO thin film and are deposited on the surface of the substrate processing apparatus may be decomposed to form fine particles (or particles). In addition, as the impurities that are in the form of ZnO thin films are decomposed into the form of fine particles, the impurities are delaminated from the surface on which the particles are deposited. In addition, the impurities that are in the form of fine particles are discharged to the outside of the substrate processing apparatus through the exhaust process (S250), and thus, the inside of the substrate processing apparatus is cleaned. That is, the impurities are discharged to the outside by suction force of an exhaust unit provided in the substrate processing apparatus, and thus, the inside of the substrate processing apparatus is cleaned.

As described above, in this embodiment, the cleaning process is performed using the cleaning gas that is capable of being decomposed at the temperature less than the process temperature. That is, in accordance with an exemplary embodiment, the cleaning may be performed at a temperature of less than approximately 300° C.

As the internal temperature of the substrate processing apparatus increases during the cleaning process, a portion of a wall surface of the chamber may be peeled off when the impurities are delaminated from the surface, for example, from the wall surface of the chamber. That is, a surface inside the substrate processing apparatus may be damaged. This is a factor of generating additional impurities in addition to the deposits generated during the deposition process. Thus, after the cleaning process is completed, a large amount of impurities remain in the substrate processing apparatus. In addition, corrosion may occur inside the substrate processing apparatus due to the high temperature.

However, in this embodiment, the impurities may be delaminated from the surface of the substrate processing apparatus to clean the surface at a temperature less than that in accordance with the related art and less than the deposition process temperature. Therefore, when the impurities are delaminated from the surface, the surface inside the substrate processing apparatus may be prevented or suppressed from being peeled off together. Thus, after the cleaning process is completed, an amount of impurities remaining in the substrate processing apparatus may be reduced. In addition, as the cleaning is performed at the low temperature, the occurrence of the corrosion due to the high-temperature heat may be suppressed or prevented.

When the cleaning is performed by injecting the cleaning gas and the first auxiliary gas (S210 and S220), plasma may be generated in the substrate processing apparatus (S230). That is, when the cleaning gas and the first auxiliary gas are injected into the substrate processing apparatus, RF power may be applied. Here, the first auxiliary gas that is at least one of N₂ gas, O₂ gas, or H₂ gas may be discharged to generate plasma.

When the plasma is generated, decomposition or activation of the cleaning gas may occur more easily. That is, when compared to a case in which only a heater installed in the substrate processing apparatus operates to heat the inside of the substrate processing apparatus, in a case in which the plasma is generated in the substrate processing apparatus, the cleaning gas may be decomposed or activated at a relatively low temperature. In other words, when the plasma is generated together compared to when only the cleaning gas and the first auxiliary gas are injected, the cleaning gas may be decomposed at a lower temperature, and thus, the cleaning may be performed at a low temperature.

In the performing of the cleaning by generating the plasma (S230) while injecting the cleaning gas and the first auxiliary gas (S210 and S220), a second auxiliary gas may be additionally injected (S240). The second auxiliary gas may be a gas for improving the plasma generation efficiency, and the second auxiliary gas may be an Ar gas. That is, when the cleaning gas and the first auxiliary gas are injected into the substrate processing apparatus, and the RF power is applied to generate the plasma, if the second auxiliary gas, which is the Ar gas, is additionally injected, the plasma generation efficiency may be improved by the Ar gas.

Therefore, when compared to the case of generating the plasma by injecting only the cleaning gas and the first auxiliary gas, if the Ar gas, which is the second auxiliary gas, is injected together, the cleaning gas may be decomposed at a relatively low temperature, and thus, the cleaning gas may be decomposed at a lower temperature to perform the cleaning.

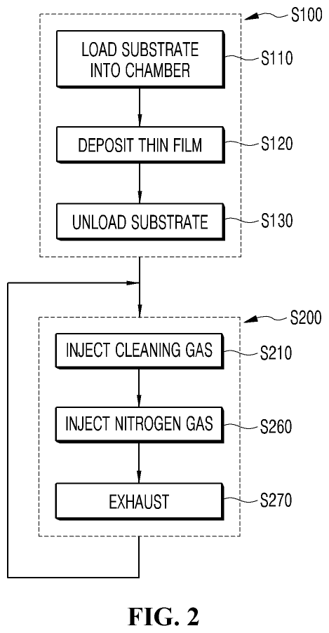

FIG. 2 is a process diagram illustrating a cleaning process in situ after a deposition process in accordance with another exemplary embodiment.

In the above-described first embodiment, it has been described that the cleaning gas containing Br and the first auxiliary gas are injected in the cleaning process (S200). However, the present disclosure is not limited thereto, and only a first cleaning gas may be injected.

Hereinafter, a cleaning method in accordance with another exemplary embodiment will be described with reference to FIG. 2. Here, contents overlapping with those in accordance with the foregoing embodiment will be omitted or briefly described.

Referring to FIG. 2, a cleaning process (S200) in accordance with another exemplary embodiment includes a process (S210) of injecting a cleaning gas, which is a gas containing bromine (Br), a process (S260) of injecting a gas containing nitrogen after the injection of the cleaning gas is stopped, and a process (S270) of exhausting the gases.

In the injection (S210) of the cleaning gas, the cleaning gas is pulsed and injected. That is, a cycle in which the injection (on) of the cleaning gas and the stop (off) of the injection are alternately performed is repeated several times. In the process of alternately performing the injection (on) of the cleaning gas and the stop (off) of the injection, when the injection of the cleaning gas is stopped, a nitrogen gas or a gas containing nitrogen is injected. Then, after the nitrogen gas is injected, the exhaust is performed. Then, ‘the injection (S210) of the cleaning gas, the injection (S260) of the nitrogen gas, and the exhaust process (S270)’ are repeated several times as one cycle.

As described above, the nitrogen gas is injected after the injection of the cleaning gas is stopped, and since the cleaning gas is not injected when the nitrogen gas is injected, it may be described that each of the cleaning gas and the nitrogen gas is pulsed and injected.

In this way, when the injection of the cleaning gas is stopped, and the nitrogen gas is injected, impurities are discharged out of a substrate processing apparatus by an operation of the exhaust unit. That is, the impurities reacting while the cleaning gas is injected (on) are discharged together with a nitrogen gas to the outside of the substrate processing apparatus when the injected nitrogen gas is discharged by the operation of the exhaust unit after the injection of the cleaning gas is stopped (off). Thus, it may be described that the injection (on) of the cleaning gas and the exhaust of the impurities are alternately performed. As described above, the nitrogen gas injected when the injection of the cleaning gas is stopped serves to improve exhaust efficiency of the impurities. That is, as the impurities are exhausted together by a flow in which the nitrogen gas is exhausted to the exhaust unit, there is an effect that the exhaust efficiency of the impurities is improved.

In the above description, it has been described that the exhaust is performed after the nitrogen gas is injected, but the present disclosure is not limited thereto. For example, the exhaust may be performed while injecting the nitrogen gas.

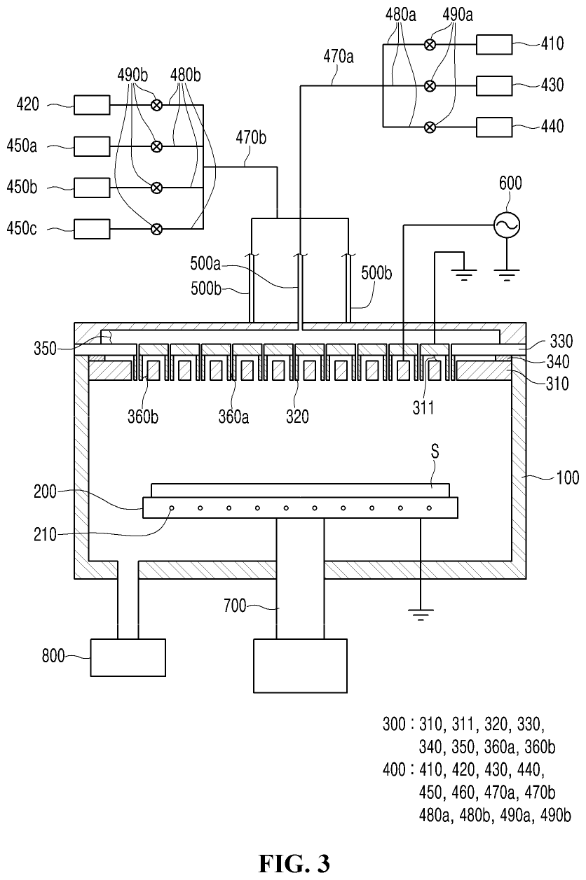

FIG. 3 is a view illustrating a substrate processing apparatus that performs cleaning through the methods in accordance with exemplary embodiments.

Hereinafter, a substrate processing apparatus in which the cleaning process according to an exemplary embodiment is performed will be described with reference to FIG. 3.

Referring to FIG. 3, a substrate processing apparatus may include a chamber 100, a support 200 installed in the chamber 100 to support a substrate S, an injection unit 300 disposed to face the support 200 so as to inject a gas into the chamber 100, a gas supply unit 400 providing a gas for deposition and cleaning to the injection unit 300, first and second gas supply tubes 500a and 500b connected to the injection unit 300 so that the first and second gas supply tubes 500a and 500b have paths different from each other, and suppling the gas provided from the gas supply unit 400 to the injection unit 300, and an RF power source unit 600 applying power so that plasma is generated in the chamber 100.

In addition, the substrate processing apparatus may further include a driving unit 700 configured to operate the support 200 in at least one of elevating and rotating operations and an exhaust unit 800 installed to be connected to the chamber 100.

The chamber 100 may include an inner space for a reaction or process capable of depositing a thin film on the substrate S loaded into the chamber 100. Here, the inner space of the chamber 100 may have, for example, a cross-sectional shape such as a quadrangular shape, a pentagonal shape, or a hexagonal shape. Of course, a shape of the inner space of the chamber 100 may be changed in various manners, the shape of the inside of the chamber 100 may be provided to correspond to that of the substrate S.

The support 200 is installed inside the chamber 100 to face the injection unit 300 and supports the substrate S loaded into the chamber 100. A heater 210 may be provided inside the support 200. Thus, when the heater 210 operates, the substrate S seated on the support 200 and the inside of the chamber 100 may be heated.

The injection unit 300 may include a first plate 310 having a plurality of holes (hereinafter, referred to as holes 311) arranged in an extension direction of the support 200 and defined to be spaced apart from each other and disposed to face the support 200 inside the chamber 100, a nozzle 320 provided so that at least a portion thereof is inserted into each of the plurality of holes 311, and a second plate 330 installed to be disposed between an upper wall inside the chamber 100 and the first plate 310 inside the chamber 100.

In addition, the injection unit 300 may further include an insulating part 340 disposed between the first plate 310 and the second plate 330.

The first plate 310 may have a plate shape extending in the extension direction of the support 200. In addition, the plurality of holes 311 are provided in the first plate 310, and each of the plurality of holes 311 may be provided to pass through the first plate 310 in a vertical direction. The plurality of holes 311 may be arranged in the extension direction of the first plate 310 or the support 200.

Each of the plurality of nozzles 320 may have a shape extending in the vertical direction, have a path through which a gas passes is provided therein, and have opened upper and lower ends. In addition, each of the plurality of nozzles 320 may be installed so that at least a lower portion thereof is inserted into the hole 311 provided in the first plate 310, and an upper portion thereof is connected to the second plate 330. Thus, the nozzle 320 may be described as a shape protruding downward from the second plate 330.

An outer diameter of the nozzle 320 may be provided to be less than an inner diameter of the hole 311. In addition, when the nozzle 320 is installed to be inserted into the hole 311, an outer circumferential surface of the nozzle 320 may be installed to be spaced apart from a peripheral wall of the hole 311 (i.e., an inner wall of the first plate 310). Thus, the inside of the hole 311 may be divided into an outer space of the nozzle 320 and an inner space of the nozzle 320.

In the inner space of the hole 311, the path in the nozzle 320 is a path through which the gas provided from the first gas supply tube 500a moves and is injected. In addition, in the inner space of the hole 311, the outer space of the nozzle 320 is a path through which the gas provided from the second gas supply tube 500b moves and is injected. Thus, hereinafter, the path within the nozzle 320 is referred to as a first path 360a, and the space outside the nozzle 320 within the hole 311 is referred to as a second path 360b.

The second plate 330 may be installed so that a top surface thereof is spaced apart from the upper wall of the chamber 100, and a bottom surface thereof is spaced apart from the first plate 310. Thus, empty spaces may be provided between the second plate 330 and the first plate 310 and between the second plate 330 and the upper wall of the chamber 100, respectively.

Here, an upper space of the second plate 330 may be a space (hereinafter, a diffusion space 350) in which the gas provided from the first gas supply tube 500a is diffused to move and may communicate with an upper opening of each of the plurality of nozzles 320. In other words, the diffusion space 350 is a space communicating with the plurality of first paths 360a. Thus, the gas passing through the first gas supply tube 500a may be diffused in the extension direction of the second plate 330 in the diffusion space 350 and then may pass through the plurality of first paths 360a and be injected downward.

In addition, a gun drill (not shown), which is a path through which gas moves, may be provided inside the second plate 330, and the gun drill may be connected to the second gas supply tube 500b and provided to communicate with the second path 360b. Thus, the gas provided from the second gas supply tube 500b may be injected toward the substrate S through the gun drill of the second plate 330 and the second path 360b.

The RF power source unit 600 is a unit that applies power to generate plasma in the chamber 100. More specifically, the RF power source unit 600 may be a unit that applies RF power for the plasma generation and may be connected to a first plate 510 of the injection unit 300. Here, the second plate 330 and the support 200 may be grounded. In addition, the RF power source unit 600 may include an impedance matching circuit that matches a source impedance with a load impedance of a power source for the plasma generation. The impedance matching circuit may include two impedance elements including at least one of a variable capacitor or a variable inductor.

The gas supply unit 400 provides a gas that is necessary for depositing the thin film and a gas that is necessary for cleaning to the injection unit 300.

The gas supply unit 400 may include a source gas storage part in which a source gas for depositing the thin film is stored, a reactant gas storage part 420 in which a reactant gas, which is a gas that reacts with the source gas, is stored, a purge gas storage part 430 in which a purge gas is stored, a cleaning gas storage part 440 in which the cleaning gas containing bromine (Br) is stored, and first and second auxiliary gas storage parts 450a and 450b in which first and second auxiliary gases injected together with the cleaning gas during the cleaning process are respectively stored. Also, the gas supply unit may include a nitrogen gas storage part 450c in which a gas containing nitrogen is stored.

In addition, the gas supply unit 400 may include a first transfer tube 470a connecting the source gas storage part 410, the purge gas storage part 430, and the cleaning gas storage part 440 to a first gas supply tube 500a and a second transfer tube 470b connecting the reactant gas storage part 420, the first auxiliary gas storage part 450a, the second auxiliary gas storage part 450b, and the nitrogen gas storage part 450c to a second gas supply tube 500b.

In addition, the gas supply unit 400 may include a plurality of first connection tubes 480a connecting each of the source gas storage part 410, the purge gas storage part 430, and the cleaning gas storage part 440 to the first transfer tube 470a, a plurality of second connection tubes 480b connecting each of a plurality of first valves 490a respectively installed in the first connection tubes 480a, the reactant gas storage part 420, the first auxiliary gas storage part 450a, the second auxiliary gas storage part 450b, and the nitrogen gas storage part 450c to the second transfer tube 470b, and a second valve 490b installed in each of the plurality of second connection tubes 480b.

A gas stored in the source gas storage part 410 is a gas for depositing the thin film. That is, at least one of a gas containing zinc (Zn), a gas containing indium (In), a gas containing gallium (Ga), or a gas containing tin (Sn) may be stored in the source gas storage part 410. Here, the source gas storage part 410 may be provided in plurality. That is, all of the source gas storage part storing the zinc (Zn)-contained gas, the source gas storage part storing the indium (In)-contained gas, the source gas storage part storing the gallium (Ga)-contained gas, and the source gas storage part storing the tin (Sn)-contained gas may be provided. Of course, some of the source gas storage part storing the zinc (Zn)-contained gas, the source gas storage part storing the indium (In)-contained gas, the source gas storage part storing the gallium (Ga)-contained gas, and the source gas storage part storing the tin (Sn)-contained gas may be provided in accordance with types of thin films to be deposited.

At least one of diethyl zinc (Zn(C₂H₅)₂)(DEZ)) or dimethyl zinc (Zn(CH₃)₂)(DMZ)) may be used as the gas containing zinc (Zn), at least one of trimethyl indium ((In(CH₃)₃) (TMIn)) or diethylamino propyl dimethyl indium (DADI) may be used as the gas containing indium (In), and trimethyl gallium ((Ga(CH₃)₃) (TMGa)) may be used as the source gas containing gallium (Ga). In addition, tetramethyltin (Sn(Me)4) may be used as the gas containing tin (Sn).

The reactant gas storage part 420 stores the gas for depositing the thin film and reacting with the source gas. The reactant gas may be a gas including oxygen (O). More specifically, at least one of pure oxygen (O₂), nitrous oxide (N₂O), or ozone (O₃) may be used as the reactant gas.

The purge gas stored in the purge gas storage part 430 may be, for example, an N₂ gas or an Ar gas.

The cleaning gas stored in the cleaning gas storage part 440 contains bromine (Br). As a more specific example, a gas containing at least one of HBr, KBr, Br₂, HBr O₃, or CBr F₃ may be stored in the cleaning gas storage part 440.

The gas stored in the first auxiliary gas storage part 450a reacts with the cleaning gas to store the first auxiliary gas serving to decompose the cleaning gas. Here, at least one of an N₂ gas, an O₂ gas, or an H₂ gas may be used as the first auxiliary gas.

The second auxiliary gas storage part 450b stores the second auxiliary gas, which is a gas for improving plasma formation efficiency. Here, the second auxiliary gas may be an Ar gas.

In the above description, it has been described that the reactant gas storage part and the first auxiliary gas storage part are separately provided. However, when the same gas is used as the reactant gas and the first auxiliary gas, only one of the reactive gas storage part and the first auxiliary gas storage part may be provided. For example, when O₂ is used as the reactant gas during thin film deposition, and O₂ is used as the first auxiliary gas during the cleaning process, only one of the reactant gas storage part and the first auxiliary gas storage part may be provided.

In addition, it has been described above that the purge gas storage part and the second auxiliary gas storage part are separately provided. However, when the same gas is used as the purge gas and the second auxiliary gas, only one of the purge gas storage part and the second auxiliary gas storage part may be provided. For example, when Ar is used as the purge gas during thin film deposition, and Ar is used as the second auxiliary gas during the cleaning process, only one of the purge gas storage part and the second auxiliary gas storage part may be provided.

Hereinafter, the deposition process using the substrate processing apparatus and the cleaning process in accordance with an exemplary embodiment will be described with reference to FIGS. 1 and 3.

First, the deposition process (S100) will be described. Here, the formation of the ZnO thin film on the substrate will be described as an example.

The substrate S is loaded into the chamber 100 and seated on the support 200. In addition, the heater 210 operates to heat the substrate S seated on the support 200 at a temperature of approximately 300° C. to approximately 350° C. Alternatively, after heating the support 200 at the temperature of approximately 300° C. to approximately 350° C., the substrate S may be seated on the support 200.

Next, the ZnO thin film is deposited on the substrate S. That is, the ZnO thin film is formed on the substrate S by an atomic layer deposition method in which the injection of the source gas, the injection of the purge gas (primary purge), the injection of the reaction gas, and the injection of the purge gas (secondary purge) are sequentially performed.

A method for forming the ZnO thin film by injecting a gas into the chamber 100 using the injection unit 300 and the gas supply unit 400 will be briefly described below.

First, the source gas stored in the source gas storage part 410, that is, the Zn-contained gas is supplied to the first transfer tube 470a. The source gas supplied to the first transfer tube 470a is introduced into a diffusion space 350 in the injection unit 300 through the first gas supply tube 500a. Then, the source gas is diffused in the diffusion space 350 to pass through a plurality of nozzles 320, that is, a plurality of first paths 360a and then is injected onto the substrate S.

When the injection of the source gas is stopped or completed, the purge gas is provided through the purge gas storage part 430 to inject the purge gas into the chamber 100 (primary purging). Here, the purge gas discharged from the purge gas storage part 430 may pass through the first transfer tube 470a and the first gas supply tube 500a and then may be injected downward through the first paths 360a. In addition, when the purge gas injected into the chamber 100 through the first paths 360a is exhausted toward the exhaust unit 800, at least a portion of by-products or impurities such as the source gas that is not adsorbed to the substrate S may be exhausted together.

Next, the reactant gas, for example, the O₂ gas may be provided from the reactant gas storage part 420 and then be injected into the chamber 100. In this case, the reactant gas may be injected into the chamber 100 through a path different from the path of the purge gas. That is, the reactant gas may pass through the second transfer tube 470b and the second gas supply tube 500b and then be injected downward through the second paths 360b. In addition, when the reactant gas is injected, the RF power source unit 600 may operate to generate plasma in the chamber 100. When the reactant gas is injected, a reaction between the source gas adsorbed on the substrate S and the reactant gas may occur to generate a reactant, that is, ZnO. Then, the reactant is accumulated or deposited on the substrate S to deposit the ZnO thin film on the substrate S.

When the reactant gas injection is stopped, the purge gas is supplied through the purge gas storage part 430 to inject the purge gas into the chamber 100 (secondary purging). In this case, by-products of the reaction between the source gas and the reactant gas may be discharged to the outside of the chamber 100 by the secondary purging.

The process cycle performed in the order of ‘the injection of the source gas, the injection of the purge gas (primary purge), the injection of the reactant gas, and the injection of the purge gas (secondary purge)’ as described above may be repeated several times. In addition, the number of times of the process cycle to be performed may be determined in accordance with the target thickness.

When the ZnO thin film having a target thickness is formed on the substrate S, the substrate S is unloaded to the outside of the chamber 100.

Thereafter, the inside of the chamber 100 is cleaned (S200). That is, during the process of depositing the ZnO thin film on the substrate S, the cleaning is performed to remove the impurities, which are the thin film deposited on an inner wall of the chamber, the surface of the support, etc., which are installed inside the chamber 100, in addition to the substrate S.

For this, the cleaning gas and the first auxiliary gas are discharged from the cleaning gas storage part 440 and the first auxiliary gas storage part 450a, respectively. The cleaning gas is injected into the chamber 100 through the first paths 360a of the injection unit 300 via the first transfer tube 470a and the first gas supply tube 500a (S210). In addition, the first auxiliary gas is injected into the chamber 100 through the second path 360b of the injection unit 300 via the second transfer tube 470b and the second gas supply tube 500b (S220). Here, the cleaning gas may be, for example, an HBr gas, and the first auxiliary gas may be an H₂ gas. In addition, the inside of the chamber 100 is adjusted to a temperature of less than approximately 300° C. by using the heater 210.

When the cleaning gas (HBr gas) and the first auxiliary gas (H₂ gas) are injected, the cleaning gas is decomposed by the first auxiliary gas. That is, H and Br in the HBr gas are decomposed. Then, a reaction occurs between the Br decomposed from the cleaning gas and the impurities remaining in the chamber 100, that is, the ZnO thin film (see Reaction Formula 1). That is, the ZnO impurities that are in the form of a thin film deposited on surfaces of various components or structures inside the chamber 100 may react with Br in the cleaning gas, and thus, Zn Br₂·H₂O may be generated by this reaction. When Zn Br₂·H₂O is generated by the reaction of the ZnO impurities that are in the form of the thin film with Br in the cleaning gas, the ZnO impurities that are in the form of the thin film may be micronized. In addition, as the impurities that are in the form of the thin film are micronized, coupling or bonding force between the impurities and the surface may be weakened, and thus, the impurities that are in the form of fine particles may be delaminated from the deposition surface.

In addition, suction force is generated inside the chamber 100 by the operation of the exhaust unit 800. Thus, the micronized impurities or the delaminated impurities are discharged to the outside of the chamber 100 through the exhaust unit 800 by the suction force, and as a result, the inside of the chamber 100 is cleaned.

In addition, when the cleaning gas and the first auxiliary gas are injected into the chamber 100 as described above, the RF power source unit 600 may operate to generate plasma in the chamber 100 (S230). That is, when the RF power source unit 600 operates, the first auxiliary gas, for example, the Oz gas may be discharged to generate the plasma. When the plasma is generated as described above, the cleaning may be performed at a temperature less than that in a case in which the plasma is not generated. That is, when compared to when only the heater 210 operates to heat the inside of the chamber 100, if the plasma is generated inside the chamber 100 together, the cleaning gas may be decomposed at a relatively low temperature, and thus, the inside of the chamber 100 may be cleaned at a lower temperature.

In addition, when the cleaning gas and the first auxiliary gas are injected into the chamber 100, and the RF power source unit 600 operates, the second auxiliary gas, that is, the Ar gas may be further injected (S240). In addition, when the second auxiliary gas is injected, plasma generation efficiency may be improved. Therefore, when compared to the case of generating the plasma by injecting only the cleaning gas and the first auxiliary gas into the chamber 100, if the Ar gas, which is the second auxiliary gas, is injected together, the cleaning gas may be decomposed at a relatively lower temperature, and thus, the inside of the chamber may be cleaned at the low temperature.

As described above, in accordance with the exemplary embodiments, the inside of the substrate processing apparatus may be cleaned at the temperature that is relatively low when compared to the related art and less than the deposition process temperature. That is, the impurities that are in the form of the thin film deposited on the surface of the component or structure installed inside the chamber 100 may be decomposed into the fine particles at the low temperature of less than approximately 300° C. to delaminate the impurities from the surface. Therefore, the inside of the chamber 100 may be cleaned at the temperature lower than the deposition temperature.

In addition, since the inside of the chamber 100 is cleaned at the low temperature, when the impurities are delaminated from the surface, the surface inside the substrate processing apparatus may be prevented or suppressed from being peeled off together. Thus, after the cleaning process is completed, an amount of impurities remaining in the substrate processing apparatus may be reduced. In addition, as the cleaning is performed at the low temperature, the occurrence of the corrosion due to the high-temperature heat may be suppressed or prevented.

### INDUSTRIAL APPLICABILITY

In accordance with the exemplary embodiments, the inside of the substrate processing apparatus may be cleaned at the temperature that is relatively low when compared to the related art and less than the deposition process temperature. That is, the impurities having the form of the thin film, which are deposited on the surface of the component or structure installed inside the substrate processing apparatus may be delaminated from the surface so as to be cleaned at the low temperature. Thus, the surface inside the substrate processing apparatus may be prevented from being peeled off together when the impurities are delaminated. Therefore, the generation of the additional contaminants in the chamber may be reduced, and the amount of impurities remaining in the substrate processing apparatus after the cleaning process is completed may be reduced. In addition, the occurrence of the corrosion of the substrate processing apparatus due to the high-temperature heat may be prevented or suppressed.

1. A method for cleaning a substrate processing apparatus, comprising:
loading a substrate into a chamber;
injecting a gas containing at least one of Zn, Ga, In, or Sn into the chamber to deposit a thin film on the substrate;
unloading the substrate to the outside of the chamber;
injecting a cleaning gas containing Br into the chamber; and
exhausting byproducts generated through a reaction between impurities deposited inside the chamber in addition to the substrate and the cleaning gas in the depositing of the thin film.

2. A method for cleaning a substrate processing apparatus, comprising:
loading a substrate into a chamber;
injecting a gas into the chamber to deposit a thin film on the substrate;
unloading the substrate to the outside of the chamber;
injecting a cleaning gas containing Br into the chamber; and
exhausting byproducts generated through a reaction between impurities deposited inside the chamber in addition to the substrate and the cleaning gas in the depositing of the thin film,
wherein in the injecting of the cleaning gas, the cleaning gas is pulsed and injected or the cleaning gas and the exhausting of the byproducts are alternately repeated.

3. The method for cleaning a substrate processing apparatus of claim 1, further comprising injecting a first auxiliary gas, which decomposes the cleaning gas, into the chamber.

4. The method for cleaning a substrate processing apparatus of claim 3, wherein the first auxiliary gas uses at least one of an H₂ gas or an O₂ gas.

5. The method for cleaning a substrate processing apparatus of claim 1, further comprising generating plasma in the chamber.

6. The method for cleaning a substrate processing apparatus of claim 5, wherein the generating of the plasma comprises injecting a second auxiliary gas that is an Ar gas.

7. The method for cleaning a substrate processing apparatus of claim 2, further comprising injecting a gas containing nitrogen into the chamber,
wherein the injecting of the gas containing the nitrogen is performed between the injecting of the cleaning gas and the exhausting of the byproducts.

8. The method for cleaning a substrate processing apparatus of claim 1, wherein the cleaning gas uses a gas containing at least one of HBr, KBr, Br₂, HBr O₃, or CBr F₃.

9. The method for cleaning a substrate processing apparatus of claim 1, wherein a temperature inside the chamber is less than a temperature when the deposition is performed.
